(19) United States
(12) Patent Application Publication
(10) Pub. No.: US 2012/0152318 A1
(43) Pub. Date: Jun. 21, 2012

(54) WATER TANK HAVING A POWER-GENERATING FUNCTION

(76) Inventor: Seung Cheol Kee, Ansan-si (KR)

(21) Appl. No.: 13/393,221

(22) PCT Filed: Aug. 27, 2010
(86) PCT No.: PCT/KR2010/005786

§ 371 Date: Feb. 28, 2012

(30) Foreign Application Priority Data
Aug. 28, 2009 (KR) 10-2009-0080257
Dec. 11, 2009 (KR) 10-2009-0123504

(51) Int. Cl. H01L 31/052; B65D 88/10

(52) U.S. Cl. 136/246; 220/565

(57) ABSTRACT

Disclosed is a water tank having a power-generating function. The disclosed water tank having a power-generating function comprises: a storage unit, the interior of which has a water storage space, and having an open top and a bottom comprising an outlet portion; and a solar cell module which is mounted on the top of the storage unit, such that an inlet portion is formed to feed water into the storage unit, and which receives solar light and generates electrical energy. Water such as rainwater can be fed into the water tank through the inlet portion formed at the periphery of the solar cell module and stored in the water tank, and water stored in the water tank can be used as needed. The solar cell module is mounted on the top of the water tank, and thus does not occupy space, which prevents the problem of occupying land and reduces general costs related thereto. As described above, the solar cell module, which might otherwise occupy a large amount of space, and a water tank are coupled together, to thereby reduce the costs associated with purchasing land.

### TECHNICAL FIELD

The present invention relates to a water tank having a power-generating function, and more particularly, to a water tank having a power-generating function which stores rainwater, etc. and uses such stored water or sunlight to generate electrical energy.

### BACKGROUND ART

Global water shortage has worsened due to global warming and climate change, and methods for storing and utilizing rainwater, etc. have been disclosed to effectively use limited water resources.

For example, a water tank which is installed to store rainwater or underground water is too large in size and occupies massive space. Such water tank causes economic burden to utilization of land and space of buildings while being used only for storing water. To that end, the water tank should be improved.

A power-generating apparatus which burns fossil fuel to generate electrical energy emits CO₂ during a power-generating process.

CO₂ which is caused during the power-generating process destroys the ozone layer and facilitates the global warming. In this regard, regulations for restricting CO₂ emission are in effect worldwide, and a new power-generating apparatus which does not emit CO₂ should be developed.

To reduce the CO₂ emission, a power-generating apparatus which uses clean energy such as the sun, water, wind, and tidal energy has been developed.

For example, a solar power-generating apparatus which uses sunlight is easy to manufacture and install, and thus is widely used as relevant technology has been developed and installation costs are not very high.

Such sunlight power-generating apparatus varies in power-generating capacity depending on the power-generating area and the amount of sunshine.

FIG. 1 is a perspective view of a conventional power-generating apparatus.

Referring to FIG. 1, to install the conventional solar power-generating apparatus 200, a large tract of land should be purchased and excavated to secure an installation place for the solar power-generating apparatus 200.

An anchor is formed by using concrete and a supporter 210 is installed at an appropriate interval in the anchor within the installation space.

Such supporter 210 includes a vertical structure, and on a top of which a frame 220 is installed to be coupled with a solar power-generating panel 222.

The top of the frame 220 is coupled to the solar power-generating panel 222 to use solar light and generate electrical energy.

To do the foregoing, the frame 220 is inclinedly installed so that the solar power-generating panel 222 is in the direction where the sunlight is emitted.

However, there are a lot of limitations in purchasing the land as the solar power-generating apparatus occupies a large area, incurring massive costs as a result of purchase of land and compensation. Also, support of local people should be ensured to install large-scale power-generating facilities.

The solar power-generating apparatus which is installed in land causes vast heat during the power-generating process using sunlight, and the land where the power-generating apparatus is installed also transmits vast heat. The heat which is transmitted to the solar power-generating apparatus deteriorates performance of a solar cell module and causes malfunction, and deteriorates the power-generating efficiency of the solar power-generating apparatus.

Regarding the conventional solar power-generating apparatus, the ground should be hardened to stably install the supporter, and the ground work should be performed by using concrete to install such supporter. Such ground treatment costs increase initial installation costs.

### DISCLOSURE

### Technical Problem

The present invention has been made to solve the problems and it is an object of the present invention to provide a water tank having a power-generating function which has a solar power-generating apparatus installed therein to generate electrical energy with sunlight and collect water including rainwater.

### Technical Solution

In order to achieve the object of the present invention, a water tank having a power-generating function comprises a storage unit, the interior of which has a water storage space, and having an open top and a bottom comprising an outlet portion; and a solar cell module which is mounted on the top of the storage unit, such that an inlet portion is formed to feed water into the storage unit, and which receives sunlight and generates electrical energy.

The solar cell module is inclinedly installed in a direction where the amount of sunshine increases.

The top of the storage unit is inclinedly formed at an angle corresponding to an angle at which the solar cell module is inclined.

The water tank having the power-generating function further comprises a filter which is installed in the inlet portion and filters impurities not to allow the impurities to enter the storage unit.

The water tank is plurally provided and is connected to another adjacent water tank.

The water tank having the power-generating function further comprises a cleaning/cooling unit which supplies water to the solar cell module and cleans and cools down a surface of the solar cell module.

The cleaning/cooling unit comprises a pump to pump up water stored in the storage unit, and a water supply unit to be connected with the pump and supply water to the surface of the solar cell module.

The cleaning/cooling unit further comprises an auxiliary pump to pump up water from an external water supply source to supply the water to the storage unit.

### BRIEF DESCRIPTION OF DRAWINGS

FIG. 1 is a perspective view of a conventional solar power-generating apparatus.

FIG. 2 is a perspective view of a water tank having a power-generating function according to an exemplary embodiment of the present invention.

FIG. 3 is a lateral view of the water tank having the power-generating function according to the exemplary embodiment of the present invention.

FIG. 4 is a perspective view of the water tank having a power-generating function that is installed continuously according to the exemplary embodiment of the present invention.

FIG. 5 is a lateral view of the water tank having the power-generating function that is installed continuously according to the exemplary embodiment of the present invention.

FIG. 6 is a perspective view of a water tank having a power-generating function according to another exemplary embodiment of the present invention.

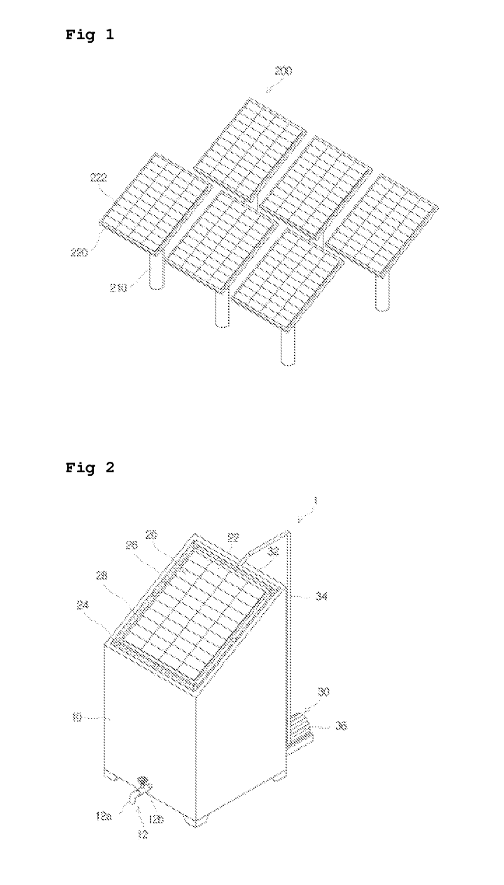

### BEST MODE

The present invention may have various amendments and exemplary embodiments, and particular exemplary embodiments will be shown in drawings and described in detail in the best mode. The exemplary embodiments may be embodied in various forms without being limited to the exemplary embodiments set forth herein. This does not limit the present invention to particular exemplary embodiments and should be understood as including all amendments, equivalents and replacements included in the spirit and scope of the present invention. Descriptions of well-known parts are omitted for clarity.

Hereinafter, an exemplary embodiment of a water tank having a power-generating function according to the present invention will be described in detail with reference to accompanying drawings. Identical or equivalent elements will be given like reference numerals and repetitive description will be omitted.

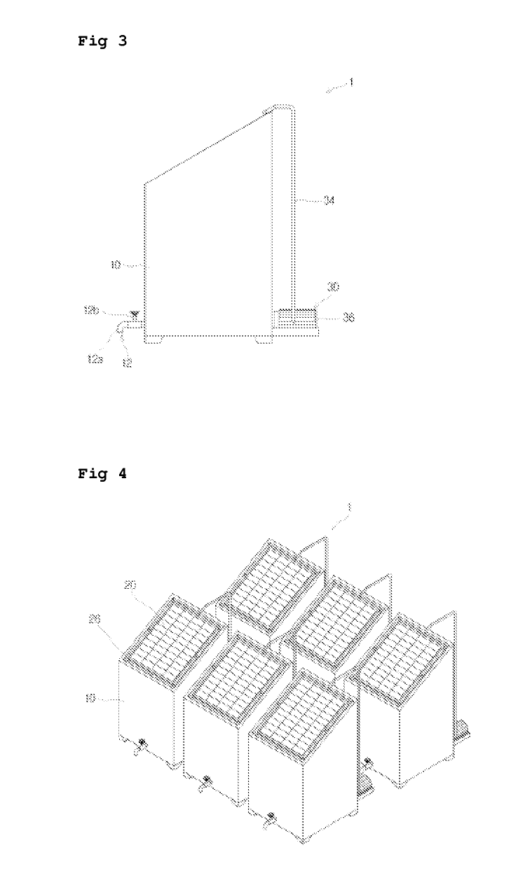

FIG. 2 is a perspective view of a water tank having a power-generating function according to an exemplary embodiment of the present invention. FIG. 3 is a lateral view of the water tank having the power-generating function according to the exemplary embodiment of the present invention.

Referring to FIGS. 2 and 3, a water tank 1 includes a storage unit 10, an outlet portion 12, a lid unit 20, a solar cell module 22, a reinforcing member 24 and an inlet portion 26.

The water tank having the power-generating function 1 according to the present exemplary embodiment includes the storage unit 10 in which a storage space is formed to store water therein.

The storage unit 10 has an open top and the outlet portion 12 in the bottom.

The outlet portion 12 includes a pipe 12a which extends to the inside of the storage unit 10, and a valve 12b as control means may be installed in the pipe 12a to control discharge of the stored water.

The lid unit 20 may be installed on the top of the storage unit 10.

The lid unit 20 includes the solar cell module 22 installed on the top thereof. The solar cell module 22 may generate electrical energy by using sunlight.

The lid unit 20 is fixed by the reinforcing member 24 such as a rib installed on the top of the storage unit 10.

The lid unit 20 may be fixed by the reinforcing member 24 by being spaced at a predetermined interval from the storage unit 10, and the inlet portion 26 is provided in the space between the lid unit 20 and an upper end of the storage unit 10 to feed water therethrough.

According to the present exemplary embodiment, the inlet portion 26 provided between the lid unit 20 and the storage unit 10 is open, but not limited thereto. Alternatively, a filter 28 may be installed on the top of the inlet portion 26 to prevent any impurities from entering the storage unit 10.

The filter 28 which is installed in the inlet portion 26 may include a mesh net or a punching net with a plurality of holes.

The inlet portion 26 has a central portion which is formed to be inclined downwardly in a lengthwise direction, and at least one continuous or discontinuous holes may be formed on the central portion thereof to feed water therethrough.

According to the present exemplary embodiment, the lid unit 20 includes the solar cell module 22 which is installed on the top thereof, but not limited thereto. Alternatively, the lid unit 20 may not be provided, and the solar cell module 22 may function as the lid unit 20.

An electrode terminal may be installed in the solar cell module 22. A power cable which is connected to the outside is installed in the electrode terminal, and is used to transmit electrical energy generated by the solar cell module 22 to the outside or to store such energy in a storage battery.

The solar cell module 22 may be inclinedly installed in the direction where the amount of sunshine increases.

For example, the solar cell module 22 according to the present exemplary embodiment may be inclinedly installed at an angle of 20 to 45 degrees toward south, and may be fixed in the direction where the amount of sunshine supplied to the solar cell module 22 is the maximum. The direction where the amount of sunshine increases may be determined in consideration of the place where the water tank having the power-generating function 1 according to the present exemplary is installed, including longitude and location, and the degree of inclination of the land and the relationship with surrounding topography.

The top of the storage unit 10 may be inclinedly formed at an angle corresponding to the angle at which the solar cell module 22 is installed.

As the top of the storage unit 10 is formed at the angle corresponding to the angle of the solar cell module 22, the solar cell module 22 may be stably supported, and the distance between the inlet portion 26 between the solar cell module 22 and the storage unit 10 is narrower to prevent rainwater from being sloshed or flowing.

The top of the storage unit 10 may be inclined inwardly toward the storage space, and rainwater which hits the top may be guided to flow into the storage space.

The solar cell module 22 may be installed to cover the entire top of the storage unit 10. If the water tank 1 is installed continuously, it may be installed in consideration of size and distance not to cover the sunlight for the solar cell module 22 installed in the water tank 1 in a rear side.

That is, the top of the water tank 1 may be shaped in an inclined rectangle, or in a forwardly or backwardly inclined pentagon.

The water tank 1 may be manufactured by synthetic resin, metal or concrete or other various materials or composite materials to maintain the shape of the water tank 1.

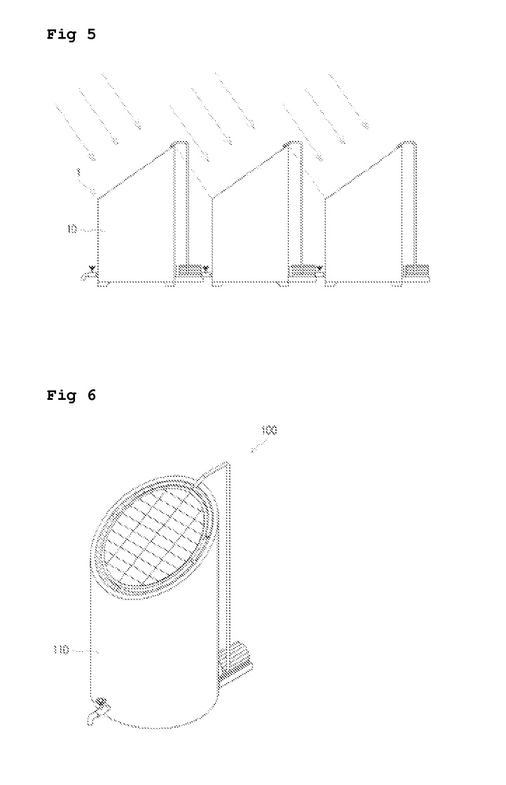

FIG. 4 is a perspective view of the water tank having the power-generating function that is installed continuously according to the exemplary embodiment of the present invention. FIG. 5 is a lateral view of the water tank having the power-generating function that is installed continuously according to the exemplary embodiment of the present invention.

According to the present exemplary embodiment, the water tank 1 may be solely installed, or plurally installed as in FIGS. 4 and 5 and connected to other adjacent water tanks 1. To do the foregoing, the water tank 1 may be connected to another adjacent water tank 1 through a pipe.

The water tank 1 may be installed at different heights, and the upper water tank 1 may be connected to the lower water tank 1 through a pipe to supply water from the upper water tank 1 to the lower water tank 1.

The water tank having the power-generating function 1 according to the present exemplary embodiment may further include a cleaning/cooling unit 30 to supply water to the solar cell module 22, and clean and cool down the surface of the solar cell module 22.

The cleaning/cooling unit 30 may transmit additionally supplied water to the solar cell module 22, and more preferably, may pump up and supply water from the storage unit 10 to the solar cell module 22.

To do the foregoing, the cleaning/cooling unit 30 may include a pump 36 to pump up water from the storage unit 10, and a water supply unit to be connected to the pump 36 and supply water to the top of the solar cell module 22.

The pump 36 has a pipe connected to an induction portion and extending to the inside of the storage unit 10, and may be connected to the water supply unit by the pipe 34 connected to a discharger.

The water supply unit may be shaped like a spray, and may include, e.g., a spray pipe 32 which is elongated across the top of the solar cell module 22.

A plurality of holes or nozzles is formed in the spray pipe 32 so that water is supplied to all over the solar cell module 22.

A filtering net (not shown) may be installed in an end part of the pipe extending to the inside of the storage unit 32 to prevent impurities of water stored in the storage space from entering the pump 36.

When rainwater is insufficient as in the dry season, the cleaning/cooling unit 30 may supply water additionally, or pump up water from a water supply source including underground water by using electrical energy generated by the solar cell module 22 and supply the water to the storage unit 10 of the water tank 1, and clean or cool down the solar cell module 22 by using the water stored in the storage unit 10.

To do the foregoing, the cleaning/cooling unit 30 may further include an auxiliary pump to pump up water from a water supply source including underground water.

According to the present exemplary embodiment, the cleaning/cooling unit 30 has the auxiliary pump supplying water from the water supply source to the storage unit 10, but not limited thereto. Alternatively, the auxiliary pump may directly supply water from the water supply source to the water supply unit to clean and cool down the solar cell module 22.

The water tank 1 may have the storage unit 10 whose overall section is rectangular. If the section of the storage unit 10 is rectangular, the distance between the continuous water tanks 1 may be shortened and continuous construction or installation of the water tank 1 may be performed without difficulty.

According to the present exemplary embodiment, the section of the storage unit 10 is rectangular, but not limited thereto. Alternatively, the section of the storage unit 10 may vary including circular, triangular and polygonal shapes.

FIG. 6 is a perspective view of a water tank having a power-generating function according to another exemplary embodiment of the present invention.

As shown therein, a water tank 100 may have a storage unit 110 whose overall section is cylindrical.

If the section of the storage unit 110 of the water tank 100 is cylindrical, it may have the largest volume in the unit area and is good for strength against water and for maintaining sealing.

Although a few exemplary embodiments have been shown and described, it will be appreciated by those skilled in the art that changes may be made in these exemplary embodiments without departing from the principles and spirit of the invention, the range of which is defined in the appended claims and their equivalents.

### INDUSTRIAL APPLICABILITY

The water tank having the power-generating function according to the present invention may store water including rainwater through an inlet portion formed at the periphery of the solar cell module, and water stored in the water tank may be used as needed.

The solar cell module is mounted on the top of the water tank, and thus does not occupy space, which prevents the problem of occupying land and reduces general costs related thereto.

As described above, the solar cell module, which might otherwise occupy a large amount of space, and a water tank are coupled to each other, to thereby reduce the costs associated with purchasing land.

The solar power generation is an eco-friendly power generation method which does not emit CO₂, and may obtain certified emission reductions (CERs) in the future. The CERs may be sold to create new income.

As the massive heat which is generated during the power-generating process and the massive heat from the ground are absorbed by water stored in the water tank, such heat is prevented from being transmitted to the solar cell module.

The heat which is generated during the power-generating process performed by the solar cell module is promptly discharged and cooled by water, preventing deterioration of performance or malfunction of the solar cell module and improving power generation efficiency.

1. A water tank having a power-generating function comprising:
a storage unit, the interior of which has a water storage space, and having an open top and a bottom comprising an outlet portion; and
a solar cell module which is mounted on the top of the storage unit, such that an inlet portion is formed to feed water into the storage unit, and which receives sunlight and generates electrical energy.

2. The water tank having the power-generating function according to claim 1, wherein the solar cell module is inclinedly installed in a direction where the amount of sunshine increases.

3. The water tank having the power-generating function according to claim 2, wherein the top of the storage unit is inclinedly formed at an angle corresponding to an angle at which the solar cell module is inclined.

4. The water tank having the power-generating function according to claim 1, further comprising a filter which is installed in the inlet portion and filters impurities not to allow the impurities to enter the storage unit.

5. The water tank having the power-generating function according to claim 1, wherein the water tank is plurally provided and is connected to another adjacent water tank.

6. The water tank having the power-generating function according to claim 1, further comprising a cleaning/cooling unit which supplies water to the solar cell module and cleans and cools down a surface of the solar cell module.

7. The water tank having the power-generating function according to claim 6, wherein the cleaning/cooling unit comprises a pump to pump up water stored in the storage unit, and a water supply unit to be connected with the pump and supply water to the surface of the solar cell module.

8. The water tank having the power-generating function according to claim 6, wherein the cleaning/cooling unit further comprises an auxiliary pump to pump up water from an external water supply source to supply the water to the storage unit.

9. The water tank having the power-generating function according to claim 2, further comprising a cleaning/cooling unit which supplies water to the solar cell module and cleans and cools down a surface of the solar cell module.

10. The water tank having the power-generating function according to claim 9, wherein the cleaning/cooling unit comprises a pump to pump up water stored in the storage unit, and a water supply unit to be connected with the pump and supply water to the surface of the solar cell module.

11. The water tank having the power-generating function according to claim 9, wherein the cleaning/cooling unit further comprises an auxiliary pump to pump up water from an external water supply source to supply the water to the storage unit.

12. The water tank having the power-generating function according to claim 3, further comprising a cleaning/cooling unit which supplies water to the solar cell module and cleans and cools down a surface of the solar cell module.

13. The water tank having the power-generating function according to claim 12, wherein the cleaning/cooling unit comprises a pump to pump up water stored in the storage unit, and a water supply unit to be connected with the pump and supply water to the surface of the solar cell module.

14. The water tank having the power-generating function according to claim 12, wherein the cleaning/cooling unit further comprises an auxiliary pump to pump up water from an external water supply source to supply the water to the storage unit.

15. The water tank having the power-generating function according to claim 4, further comprising a cleaning/cooling unit which supplies water to the solar cell module and cleans and cools down a surface of the solar cell module.

16. The water tank having the power-generating function according to claim 15, wherein the cleaning/cooling unit comprises a pump to pump up water stored in the storage unit, and a water supply unit to be connected with the pump and supply water to the surface of the solar cell module.

17. The water tank having the power-generating function according to claim 15, wherein the cleaning/cooling unit further comprises an auxiliary pump to pump up water from an external water supply source to supply the water to the storage unit.

18. The water tank having the power-generating function according to claim 5, further comprising a cleaning/cooling unit which supplies water to the solar cell module and cleans and cools down a surface of the solar cell module.

19. The water tank having the power-generating function according to claim 18, wherein the cleaning/cooling unit comprises a pump to pump up water stored in the storage unit, and a water supply unit to be connected with the pump and supply water to the surface of the solar cell module.

20. The water tank having the power-generating function according to claim 18, wherein the cleaning/cooling unit further comprises an auxiliary pump to pump up water from an external water supply source to supply the water to the storage unit.
